(19) United States
(12) Patent Application Publication
(10) Pub. No.: US 2003/0115530 A1
(43) Pub. Date: Jun. 19, 2003

(54) Fast turbo-code encoder

(76) Inventors: Yeun-Renn Ting, Taoyuan Hsien (TW); Erl-Huei Lu, Taoyuan Hsien (TW); Kuang-Shyr Wu, Taoyuan Hsien (TW); Hsien-Yu Chu, Taoyuan Hsien (TW)

Correspondence Address: J.C. Patents, Inc., 4 Venture, Suite 250, Irvine, CA, 92618, US

(21) Appl. No.: 10/033,752

(22) Filed: Dec. 19, 2001

(51) Int. Cl. H03M 13/00

(52) U.S. Cl. 714/755; 714/786

(57) ABSTRACT

The present invention provides a fast turbo-code encoder. The advantage of the encoding device is the encoding data is output via less exclusive-or (XOR) gate operations. The structure of the fast turbo-code encoding directly applies the exclusive-or operation on the input data and the internal value of the register, the encoding output is obtained via less exclusive-or gate time. Thus, the device of the present invention saves half of the gate time comparing to the conventional structure.

### BACKGROUND OF THE INVENTION

1. Field of Invention

The present invention generally relates to an encoder, and more particularly, to a fast turbo-code encoder. The advantage of the encoder is the encoding data is output via less exclusive-or (XOR) gate operations. Thus, saves about half of the operation time of the conventional structure.

2. Description of Related Art

The error control coding is widely used in the communication system and the computer media storage. Berrou, Glavieux, and Thitimajshima first proposed the turbo-code which error-correcting capability nears to the Shannon limited error-correcting in 1993 (C. Berrou, A. Glavieux, and P. Thitimajshima, “Near Shannon Limited Error-correcting Coding and Decoding: Turbo-codes (1),” in Proc. ICC'93, May, 1993). The structures of the turbo-code encoding and decoding are shown in FIG. 1 and FIG. 2. Wherein, the encoding structure comprises two recursive systematic convolution encoder (hereafter abbreviated as RSC). The characteristic of the RSC is encoding two convolution codes having the same structure together, thus the receiving end is able to decode the message repeatedly. Since the characteristic of the repeatedly decoding, thus provides the excellent error-correcting capability. And since the excellence of the error-correcting capability, the turbo-codes are widely applied in the communication system. For example, like applied in the CDMA transmission system (J. Blaanz, P. Jung, and M. Na B han, “Realistic Simulations of CDMA Mobile Radio Systems Using Joint Detection and Coherent Receiver Antenna Diversity,” IEEE third International Symposium on Spread Spectrum Techniques and Applications, Oulu Finland, 1994).

When Berrou and Benedetto proposed the turbo-codes encoding structure, the RSC and the non-recursive systematic convolution (NSC) is compared. In most of the communication conditions, the RSC has larger minimum distance of the codes and the better error-correcting efficiency. Thus, two RSC are parallelized to form a turbo-code operation structure. Whereas, since the recursive characteristic of the RSC, the encoding process has a longer time delay, this is an existing disadvantage of using the turbo-codes.

### SUMMARY OF THE INVENTION

To solve the problem mentioned above, the present invention provides a fast turbo-code decoder. The advantage of the encoder is the encoding data is output via less exclusive-or (XOR) gate operations. Thus, saves half of the operation time comparing to the conventional structure.

To achieve the objective mentioned above, the present invention provides a turbo-code fast encoding device that is suitable for the communication system. The device is suitable for outputting a parity information after the encoding process on a turbo-code of the sequential input. Wherein, the input bit sequence of the turbo-code is represented as d=(d₁,d₂, . . . ,dₖ, . . . ,d_{N}), Where the dₖ is the input bit of the turbo-code fast encoding device at time k, k is from 1 to N, and N is the segment length. Wherein, the turbo-code fast encoding device comprises a first recursive systematic convolution (RSC) encoder and a second recursive systematic convolution (RSC) encoder. The first recursive systematic convolution (RSC) encoder and the second recursive systematic convolution (RSC) encoder all have

$${y}_{k} = {d}_{k} + {\sum }_{i = 1}^{M} {g}_{di} {a}_{k - i}$$

Wherein, dₖ is the input bit of the turbo-code fast encoding device at time k, yₖ is the parity information corresponding to dₖ, g_{di} is the parameter that is generated by a first encoder feed-forward generator, the element is either 0 or 1, whereas, aₖ₋ᵢ is generated by ith register at time k.

The turbo-code fast encoding device mentioned above, wherein, the output of the first encoder at time k is represented as C_{K}=(Xₖ,Y_{1K}). Because the encoder is systematic, so Xₖ=dₖ. A parity output is represented as

$${Y}_{1 k} = {\sum }_{i = 0}^{M} {g}_{1 fi} {a}_{k - i} ,$$

herein, M is the memory order of the encoder, (g_{1f1}, g_{1f2}, . . . g_{1fM}) is defined such like G_{1f} is the first encoder feed-forward generator, the element is either 0 or 1.

The turbo-code fast encoding device mentioned above, wherein, the following equation

$${a}_{k} = {d}_{k} + {\sum }_{i = 1}^{M} {g}_{1 bi} {a}_{k - i}$$

can be obtained from the first encoder. With the same reason, (g_{1bf1}, g_{1b2}, . . . g_{1bM})=G_{1b} is called as the first encoder feedback generator, thus the following general equation is obtained:

$${y}_{1 k} = {\sum }_{i = 0}^{M} {g}_{1 fi} {a}_{k - i} = {a}_{k} + {\sum }_{i = 1}^{M} {g}_{1 fi} {a}_{k - i} = ( {d}_{k} + {\sum }_{i = 1}^{M} {g}_{ibi} {a}_{k - i} ) + {\sum }_{i = 1}^{M} {g}_{1 fi} {a}_{k - i}$$

the above equation can be re-arranged as follows:

$${y}_{1 k} = {d}_{k} + {\sum }_{i = 1}^{M} ( {g}_{1 bi} + {g}_{1 fi} ) {a}_{k - i} ≡ {d}_{k} + {\sum }_{i = 1}^{M} {g}_{1 di} {a}_{k - i}$$

The turbo-code fast encoding device mentioned above, wherein, the

$${G}_{1 d} = 1 \vert \vert {\sum }_{i = 1}^{M} {g}_{1 di} = 1 \vert \vert {\sum }_{i = 1}^{M} ( {g}_{1 bi} + {g}_{1 fi} )$$

is defined and called as the parameter of the first encoder direct-feed-forward generator, where the ∥ represents two rows of the binary numbers that are serially concatenated.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention. In the drawings,

FIG. 1 schematically shows a turbo-code encoder comprising of two parallel RSC encoders;

FIG. 2 schematically shows the decoding structure of the turbo-code;

FIG. 3 schematically shows a structure of a fast RSC encoder;

FIG. 4 schematically shows a conventional structure of a fast RSC encoder, wherein G_{f}=1101, G_{b}=1011; and

FIG. 5 schematically shows a structure of a fast RSC encoder of a preferred embodiment of the invention, wherein G_{f}=1101, G_{d}=1110.

### DESCRIPTION OF THE PREFERRED EMBODIMENTS

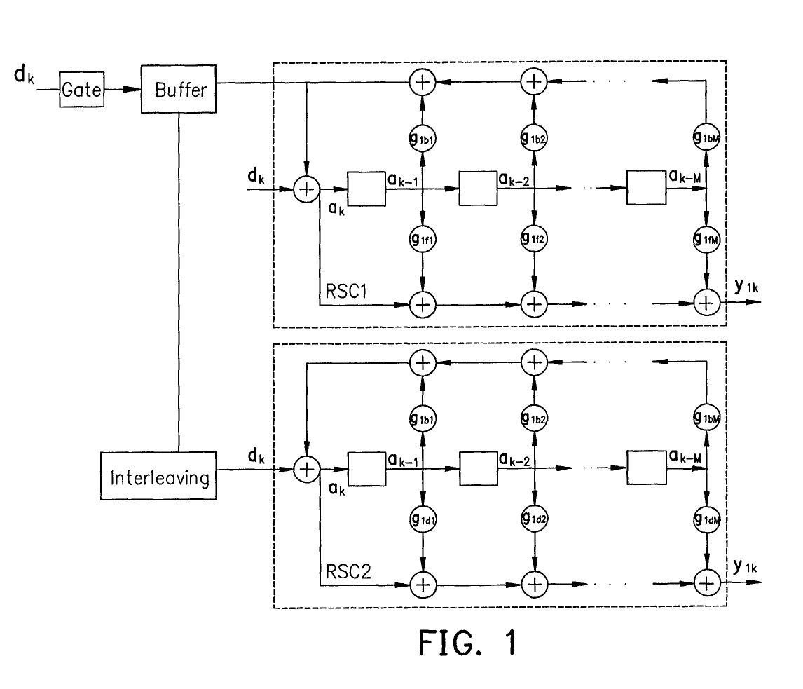

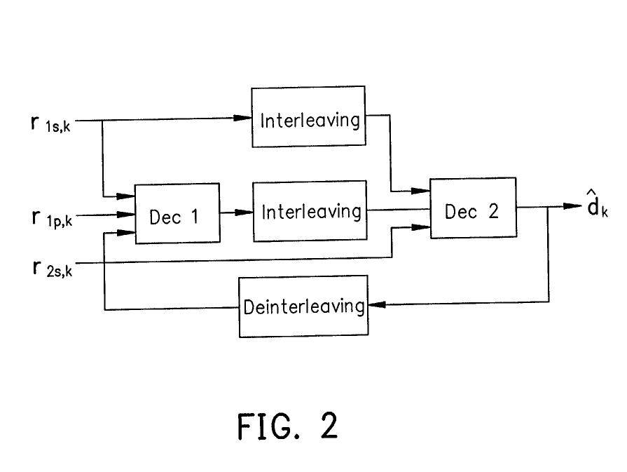

A turbo-code encoder comprises two parallel RSC encoders (RSC 1 and RSC 2 as shown in FIG. 1), the sequence of the input bit is represented as d=(d₁, d₂, . . . , dₖ, . . . , d_{N}), where the dₖ is the input bit of the encoder at time k, k is from 1 to N, and N is the segment length. The output of the first encoder RSC 1 at time k is represented as C_{K}=(Xₖ, Y_{1K}). Because the encoder is systematic, so Xₖ=dₖ. Another parity output is represented as

$${Y}_{1 k} = {\sum }_{i = 0}^{M} {g}_{1 fi} {a}_{k - i} ,$$

herein, M is the memory order of the encoder, (g_{1f1}, g_{1f2}, . . . g_{1fM}) is defined as G_{1f} is the first encoder feed-forward generator, the element is either 0 or 1. The first encoder is also called as the RSC 1 encoder. The following equation

$${a}_{k} = {d}_{k} + {\sum }_{i = 1}^{M} {g}_{1 bi} {a}_{k - i}$$

can be obtained from the encoder. With the same reason, (g_{1bf1}, g_{1b2}, . . . g_{1bM})=G_{1b} is called as the first encoder feedback generator, thus the following general equation is obtained:

$${y}_{1 k} = {\sum }_{i = 0}^{M} {g}_{1 fi} {a}_{k - i} = {a}_{k} + {\sum }_{i = 1}^{M} {g}_{1 fi} {a}_{k - i} = ( {d}_{k} + {\sum }_{i = 1}^{M} {g}_{ibi} {a}_{k - i} ) + {\sum }_{i = 1}^{M} {g}_{1 fi} {a}_{k - i} \qquad ( 1 )$$

the above equation can be re-arranged as follows:

$${y}_{1 k} = {d}_{k} + {\sum }_{i = 1}^{M} ( {g}_{1 bi} + {g}_{1 fi} ) {a}_{k - i} ≡ {d}_{k} + {\sum }_{i = 1}^{M} {g}_{1 di} {a}_{k - i} \qquad ( 2 )$$

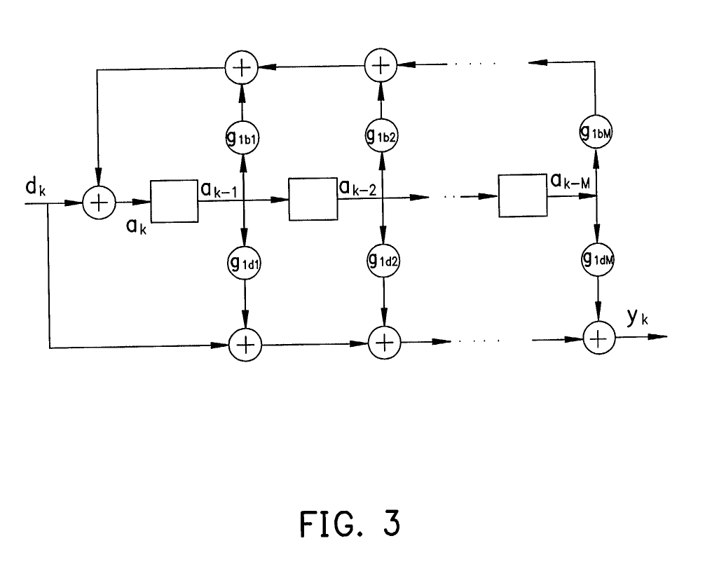

The structure of the fast RSC encoder designed based on this is shown in FIG. 3. Herein, defines

$${G}_{1 d} = 1 \vert \vert {\sum }_{i = 1}^{M} {g}_{1 di} = 1 \vert \vert {\sum }_{i = 1}^{M} ( {g}_{1 bi} + {g}_{1 fi} ) \qquad ( 3 )$$

called as the parameter of the first encoder direct-feed-forward generator, wherein, the ∥ represents two rows of the binary numbers are serially concatenated, for example, 1 ∥ 001=1001. With the same reason,

$${y}_{2 k} = {d}_{k} + {\sum }_{i = 1}^{M} {g}_{2 di} {a}_{k - i} ,$$

thus, can be written as the following general equation:

$${y}_{hk} = {d}_{k} + {\sum }_{i = 1}^{M} {g}_{hdi} {a}_{k - i} \qquad ( 4 )$$

Herein, the subscript h of y is either 1 or 2 that represents the number of the RSC encoder. The structure of the RSC encoder 1 and the RSC encoder 2 are the same in current turbo-code application. Thus, the number h is omitted, obtains

$${y}_{k} = {d}_{k} + {\sum }_{i = 1}^{M} {g}_{di} {a}_{k - i} ,$$

the circuit diagram of the RSC encoder based on this design is shown in FIG. 3.

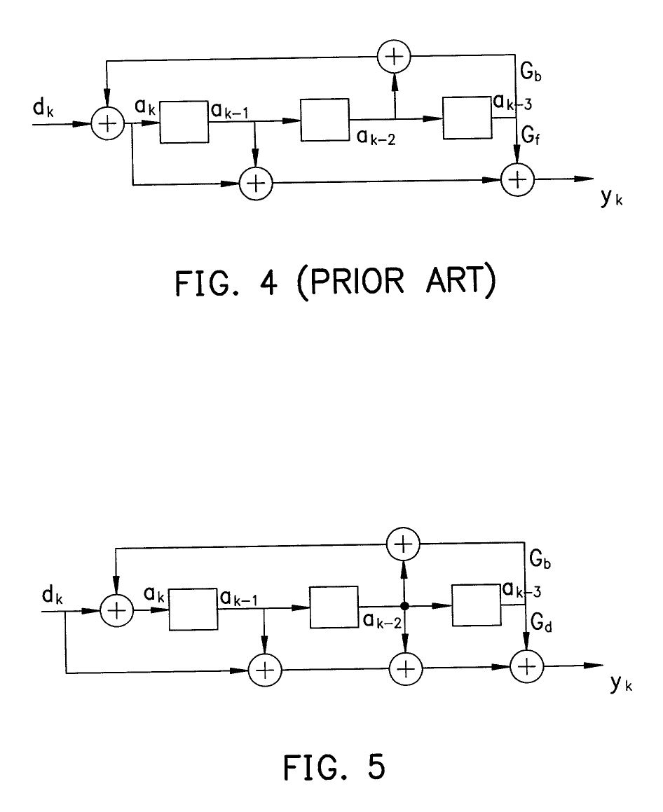

For easy to describe, the turbo-code of the third generation CDMA mobile communication standard is exemplified here as a preferred embodiment according to the present invention. The quantity of the register of the RSC encoder M=3, whereas, the RSC encoder 2 is the same as the RSC encoder 1, so g_{1bi}=g_{2bi} g_{bi} and g_{1fi}=g_{2fi} g_{bi}, where the code ratio R=⅓, as shown in FIG. 4, the parameters of the feedback generator and the feed-forward generator are G_{f}=1101, G_{b}=1011 respectively. The equation is represented as follows:

$$\begin{matrix}{y}_{k} = {d}_{k} + {\sum }_{i = 1}^{M} {g}_{fi} {a}_{k - i} = {a}_{k} + {a}_{k - 1} + {a}_{k - 3} = ( {d}_{k} + {a}_{k - 2} + {a}_{k - 3} ) + {a}_{k - 1} + {a}_{k - 3} \\ = {d}_{k} + {a}_{k - 1} + {a}_{k - 2} = 1 {d}_{k} + 1 {a}_{k - 1} + 1 {a}_{k - 2} + 0 {a}_{k - 3}\end{matrix} \qquad ( 5 )$$

From equation (5) and based on the definition of equation (3), the parameter of the direct-feed-forward generator is obtained as G_{d}=1110, thus, the RSC encoder can be simplified as shown in FIG. 5. From equation (2), the encoding structure only uses only half of the exclusive-or (XOR) gate operations comparing to the conventional encoder to encode one bit. Comparing FIG. 4 and FIG. 5, the encoder of FIG. 4 needs via four exclusive-or gate operations to encode one bit, whereas, the encoder of the FIG. 5 only needs via two exclusive-or gate operations to encode one bit, thus, the speed is double.

The present invention provides a fast turbo-code encoding method and device. Wherein, the new structure of the encoder directly processes the exclusive-or operation on the input data and the internal value of the register. Thus, the encoding output is obtained via less exclusive-or gate time. As shown in equation (2), saves about half of the operation time of the conventional structure.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

What is claimed is:

1. A turbo-code fast encoding device, the device is suitable for the communication system, the device is suitable for outputting parity information after the encoding process on a turbo-code of the sequential input, wherein, the input bit sequence of the turbo-code is represented as d=(d₁, d₂, . . . , dₖ, . . . ,d_{N}), where the dₖ is the input bit of the turbo-code fast encoding device at time k, k is from 1 to N, and N is the segment length, wherein, the turbo-code fast encoding device comprises:
a first recursive systematic convolution (RSC) encoder; and
a second recursive systematic convolution (RSC) encoder, wherein, the first recursive systematic convolution (RSC) encoder and the second recursive systematic convolution (RSC) encoder comply to
$${y}_{k} = {d}_{k} + {\sum }_{i = 1}^{M} {g}_{di} {a}_{k - i}$$
Wherein, dₖ is the input bit of the turbo-code fast encoding device at time k, yₖ is the parity information corresponding to dₖ, g_{di} is the parameter that is generated by a first encoder feed-forward generator, the element is either 0 or 1, whereas, aₖ₋ᵢ is generated by ith register at time k.

2. The turbo-code fast encoding device of claim 1, wherein, the output of the first recursive systematic convolution encoder at time k is represented as C_{K}=(Xₖ, Y_{1K}), because the encoder is systematic, so Xₖ=dₖ, a surplus code output is represented as
$${Y}_{1 k} = {\sum }_{i = 0}^{M} {g}_{1 fi} {a}_{k - i} ,$$
herein, M is the memory order of the encoder, (g_{1f1}, g_{1f2}, . . . g_{1fM}) is defined as G_{1f} is the first encoder feed-forward generator, the element is either 0 or 1.

3. The turbo-code fast encoding device of claim 1, wherein, the following equation
$${a}_{k} = {d}_{k} + {\sum }_{i = 1}^{M} {g}_{1 bi} {a}_{k - i}$$
can be obtained from the first recursive systematic convolution encoder, with the same reason, (g_{1bf1}, g_{1b2}, . . . g_{1bM})=G_{1b} is called as the first encoder feedback generator, thus the following general equation is obtained:
$${y}_{1 k} = {\sum }_{i = 0}^{M} {g}_{1 fi} {a}_{k - i} = {a}_{k} + {\sum }_{i = 1}^{M} {g}_{1 fi} {a}_{k - i} = ( {d}_{k} + {\sum }_{i = 1}^{M} {g}_{ibi} {a}_{k - i} ) + {\sum }_{i = 1}^{M} {g}_{1 fi} {a}_{k - i}$$
the above equation can be re-arranged as follows:
$${y}_{1 k} = {d}_{k} + {\sum }_{i = 1}^{M} ( {g}_{1 bi} + {g}_{1 fi} ) {a}_{k - i} ≡ {d}_{k} + {\sum }_{i = 1}^{M} {g}_{1 di} {a}_{k - i}$$

4. The turbo-code fast encoding device of claim 3, wherein, the
$${G}_{1 d} = 1 ‖ {\sum }_{i = 1}^{M} {g}_{1 di} = 1 ‖ {\sum }_{i = 1}^{M} ( {g}_{1 bi} + {g}_{1 fi} )$$
is defined and called as the parameter of the first encoder direct-feed-forward generator, where the ∥ represents two rows of the binary numbers that are serially concatenated.
